(19) United States
(12) Patent Application Publication
(10) Pub. No.: US 2026/0094594 A1
(43) Pub. Date: Apr. 2, 2026

(54) BUZZER DRIVING SYSTEM WITH SIGNAL COMPENSATION FUNCTION AND METHOD THEREOF

(71) Applicant: NUVOTON TECHNOLOGY CORPORATION, HSINCHU CITY (TW)

(72) Inventors: Pao-Shu Chang, Zhubei City (TW); Wei-Sin Chen, Zhubei City (TW)

(21) Appl. No.: 19/335,518

(22) Filed: Sep. 22, 2025

Related U.S. Application Data
(60) Provisional application No. 63/701,378, filed on Sep. 30, 2024.

(30) Foreign Application Priority Data
Jan. 24, 2025 (TW) 114103527

(51) Int. Cl. G10K 9/122; G01R 23/16

(52) U.S. Cl. CPC G10K 9/122; G01R 23/16

(57) ABSTRACT

A buzzer driving system with a signal compensation function for a buzzer is provided. The buzzer driving system includes a control module and a filter module. The control module has a neural network unit configured to generate a filter coefficient corresponding to a frequency response of the buzzer based on frequency spectrum data of the buzzer. The filter module is configured to receive an audio playback signal and filter the audio playback signal according to the filter coefficient to generate an output signal. The buzzer driving system realizes signal compensation of the buzzer by adjusting the filter coefficient, thereby preventing distortion of the output audio signal.

### CROSS-REFFERENCE TO RELATED APPLICATION

This application claims priority to U.S. Provisional Patent Application No. 63/701,378, filed on September 30, 2024, and Taiwanese Patent Application No. 114103527, filed on January 24, 2025. The entire contents of both applications are incorporated herein by reference.

### BACKGROUND

### Field of the Invention

The present invention relates to a buzzer driving system and a driving method thereof, and more particularly to a buzzer driving system and a driving method with a signal compensation function.

### Description of the Related Art

Buzzers are sound-generating components that are widely used in products such as alarms, multimedia devices, automotive electronic equipment, and toys. Buzzers are generally categorized into piezoelectric type and electromagnetic type. When a buzzer is powered, a metal diaphragm inside the buzzer vibrates within a resonance chamber to produce sound.

Conventional buzzers are typically driven by digital signals. Due to the relatively large equivalent capacitance of buzzers, ranging from tens to hundreds of nanofarads (nF), different frequency components of the signal may be attenuated or amplified depending on the frequency response of the buzzer itself. As a result, certain portions of the signal may be filtered out, causing signal distortion and degradation of audio quality. For example, short pulses in a digital signal may be filtered out by the buzzer, resulting in a loss of audio detail.

The issue of signal distortion results in output sound quality from buzzers that is inferior to that of speakers. However, compared to speakers, buzzers still possess irreplaceable advantages such as compact size, high volume output, low cost, and high durability.

### SUMMARY

Accordingly, how to overcome the limitations of existing buzzers has become an important issue for those skilled in the art.

In view of the foregoing, an aspect of the present invention is to provide a buzzer driving system with a signal compensation function and a driving method thereof, which can adjust a filter coefficient of a filter module based on the frequency response of different buzzers to perform signal compensation during filtering. This prevents signal distortion caused by the buzzer, preserves more audio details, enhances the sound quality of the buzzer, and allows the buzzer to reproduce the audio details contained in the original audio signal.

Based on an aspect of the present invention, a buzzer driving system with a signal compensation function is provided for use with a buzzer. The buzzer driving system comprises a control module and a filter module. The control module has a neural network unit configured to generate a filter coefficient corresponding to a frequency response of the buzzer based on frequency spectrum data of the buzzer. The filter module is configured to receive an audio playback signal and filter the audio playback signal based on the filter coefficient to generate an output signal.

Based on another aspect of the present invention, a buzzer driving method with a signal compensation function is further provided. The method comprises: collecting a plurality of test voltages generated by the buzzer in response to a plurality of test signals; performing Fast Fourier Transform analysis on the plurality of test voltages to generate frequency spectrum data of the buzzer; generating a filter coefficient corresponding to a frequency response of the buzzer based on the frequency spectrum data using a neural network; and filtering an audio playback signal based on the filter coefficient to generate an output signal for driving the buzzer.

In the buzzer driving system and method with a signal compensation function according to the present invention, the filter coefficient corresponding to the frequency spectrum data is generated by a trained neural network unit, which controls the filter module to adjust filter coefficient of the filter module accordingly. As a result, the signal processing performed by the filter module can match the frequency response characteristics of different buzzers, thereby enabling signal compensation during filtering and delivering sound quality and audio detail comparable to that of conventional speakers.

### BRIEF DESCRIPTION OF THE DRAWINGS

FIG. 1 is a block diagram illustrating a buzzer driving system with a signal compensation function according to an embodiment of the present invention.

FIG. 2 is another block diagram illustrating another buzzer driving system with a signal compensation function according to another embodiment of the present invention.

FIG. 3 is a flowchart illustrating a buzzer driving method with a signal compensation function according to an embodiment of the present invention.

FIG. 4 is another flowchart illustrating another buzzer driving method with a signal compensation function according to another embodiment of the present invention.

### DETAILED DESCRIPTION

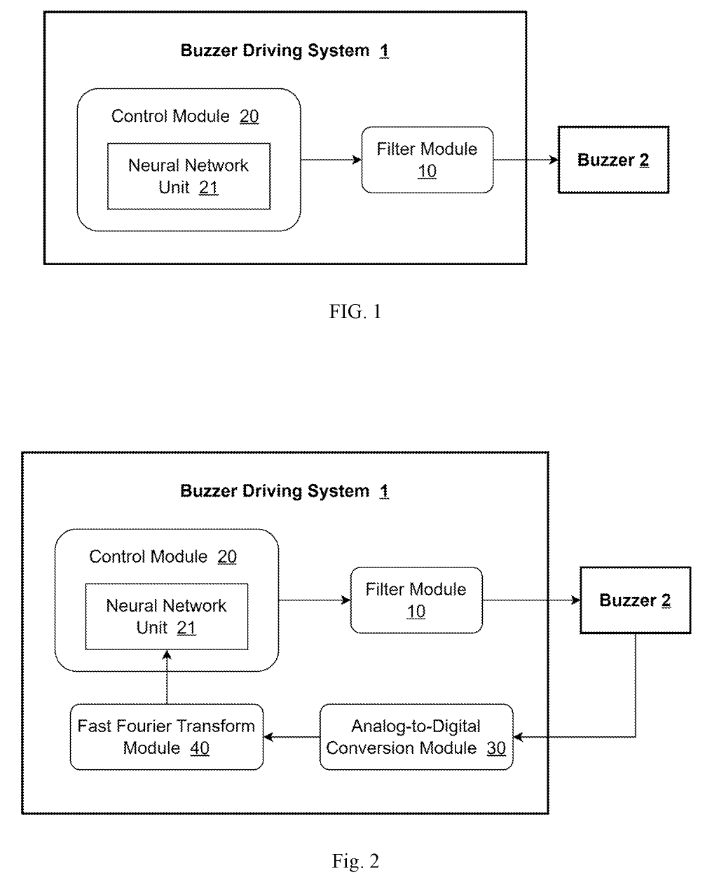

Referring to FIG. 1, an aspect of the present invention is to provide a buzzer driving system 1 with a signal compensation function, which adjusts a filter coefficient of a filter module based on the frequency response of different buzzers to perform signal compensation during filtering and prevent signal distortion caused by the buzzer, thereby preserving more audio details. The following provides a detailed description of possible embodiments of the present invention with reference to the drawings. However, it should be noted that the implementation details described below are not intended to limit the scope of the claimed invention, but are provided merely to facilitate understanding by those skilled in the art.

According to an embodiment of the present invention, the buzzer driving system 1 with a signal compensation function is electrically connected to a buzzer 2 and includes a filter module 10 and a control module 20. The buzzer driving system 1 is implemented as a system independent from the buzzer 2 and is arranged separately from the buzzer 2. Therefore, it can be directly applied to an existing buzzer 2 without requiring any modification to the structure of the buzzer 2.

The filter module 10 is electrically connected to the buzzer 2. The filter module 10 receives, from an external source, an audio playback signal corresponding to the buzzer 2 and filters the audio playback signal based on a filter coefficient to generate an output signal to drive the buzzer 2.

In an embodiment, the filter module 10 may be implemented as an active filter or a passive filter, and the filter coefficient is an adjustable parameter. For example, the filter coefficient may be adjusted by changing the number of components such as inductors, resistors, and/or capacitors that are switched into the filter module 10.

In an embodiment, the filter module 10 may include a finite impulse response (FIR) filter of N order, and the filter coefficient may be an N-order filter coefficient.

The control module 20 is electrically connected to the filter module 10 and comprises a neural network unit 21. The neural network unit 21 is configured to compute a filter coefficient corresponding to a frequency response of the buzzer 2 based on frequency spectrum data of the buzzer 2. The control module 20 may generate a control signal based on the filter coefficient and transmit the control signal to the filter module 10 to adjust the filter coefficient of the filter module 10 accordingly. The control module 20 may be implemented using a computing device such as a central processing unit (CPU), a graphics processing unit (GPU), or the like. The neural network unit 21 may include a deep neural network (DNN) model that has been pre-trained using a plurality of sample frequency spectrum data and corresponding sample filter coefficients, such that the neural network unit 21 can compute a filter coefficient corresponding to the frequency response of different buzzers based on the respective frequency spectrum data.

In some embodiments, the neural network unit 21 may be trained using one or more well-known artificial intelligence (AI) or machine learning algorithms. These algorithms may include neural networks (e.g., artificial neural networks, deep neural networks, convolutional neural networks (CNN), recurrent neural networks (RNN), autoencoders, and reinforcement learning), fuzzy logic, artificial intelligent (AI), deep learning algorithms, deep structured learning and hierarchical learning algorithms, support vector machines (SVM) (e.g., linear SVM, nonlinear SVM, and SVM regression), decision tree learning (e.g., classification and regression trees (CART)), dimensionality reduction algorithms (e.g., projection, manifold learning, and principal component analysis (PCA)), and/or deep machine learning algorithms.

The implementation of the neural network unit 21 may include at least two stages: a training stage (also referred to as a learning stage) and an inference stage (also referred to as a generation stage). The neural network unit 21 generates the filter coefficient during the inference stage.

During the training of the neural network unit 21, each piece of sample frequency spectrum data corresponds to a sample filter coefficient. The associated sample frequency spectrum data and the sample filter coefficient correspond to the same sample buzzer. The sample frequency spectrum data is related to information such as the equivalent circuit and frequency response of the corresponding sample buzzer, while the sample filter coefficient represents the filter coefficient value required to adjust the signal during filtering to match the frequency response of the corresponding sample buzzer.

Each piece of sample frequency spectrum data is generated by performing Fast Fourier Transform (FFT) analysis on a plurality of sample voltages produced when a sample buzzer receives a plurality of test signals. The signal frequencies of the test signals increase sequentially based on a predetermined frequency interval, that is, the signal frequencies of the test signals are sequentially spaced at a predetermined frequency interval. For example, if the predetermined frequency interval is 200 Hz, the test signal frequencies may be 200 Hz, 400 Hz, 600 Hz, and so on, such that each adjacent pair of test signals is spaced by 200 Hz. The plurality of test signals are superimposed to form a combined test signal that covers a wide frequency range. Preferably, each test signal has the same signal amplitude and is superimposed with the others.

The plurality of sample frequency spectrum data serves as input data for a deep learning model, while the corresponding plurality of sample filter coefficients serves as output data for the model. During the training stage, the neural network unit 21 is trained using the sample frequency spectrum data and corresponding sample filter coefficients obtained from multiple sample buzzers to establish a computational relationship between the frequency spectrum data and the filter coefficients for different buzzers.

By configuring the filter coefficient of the filter module 10 based on the frequency spectrum data corresponding to the buzzer 2, the signal processing performed by the filter module 10 can complement the signal response characteristics of the buzzer 2. For example, for a specific frequency band that is attenuated due to the characteristics of the buzzer 2, the filter module 10 can preemptively enhance the signal within that frequency band, such that even after attenuation by the buzzer 2, the signal strength of that frequency band still matches the intended amplitude of the original signal. In this way, signal distortion can be prevented.

Referring to FIG. 2, to obtain the frequency spectrum data of the buzzer 2, the buzzer driving system 1 with a signal compensation function further includes an analog-to-digital conversion module 30 and a Fast Fourier Transform (FFT) module 40. The buzzer 2 receives a plurality of test signals, which may be output from an external device to the buzzer 2. The plurality of test signals used in this stage are the same as those received by the sample buzzers during the training of the neural network unit 21.

The analog-to-digital conversion module 30 is connected to the buzzer 2 and is configured to receive a plurality of test voltages generated by the buzzer 2 in response to the plurality of test signals. The analog-to-digital conversion module 30 may include an analog-to-digital converter (ADC).

The Fast Fourier Transform (FFT) module 40 is connected to the analog-to-digital conversion module 30 and the neural network unit 21. The FFT module 40 receives the plurality of test voltages from the analog-to-digital conversion module 30 and performs Fast Fourier Transform analysis on the test voltages to generate frequency spectrum data of the buzzer 2. The frequency spectrum data is then transmitted to the neural network unit 21 as input. The FFT analysis may include, for example, transforming time-domain signals into the frequency domain. In this embodiment, the FFT module 40 may be implemented separately from the control module 20 or may be integrated with the neural network module within the control module 20.

In an embodiment, a signal processing module may be connected between the filter module 10 and the buzzer 2. The signal processing module may be configured to perform operations such as amplifying and filtering the output signal generated by the filter module 10 and then output the processed signal to the buzzer 2.

The buzzer 2 may be a piezoelectric buzzer, which primarily comprises a piezoelectric element, a metal diaphragm, and a housing. The piezoelectric element may be made of a piezoelectric ceramic material. When a voltage is applied, the piezoelectric element deforms due to the piezoelectric effect and drives the metal diaphragm to vibrate, thereby generating sound. The housing not only encases the piezoelectric element and the metal diaphragm but also forms a resonance chamber for the piezoelectric element and the metal diaphragm.

Compared to conventional speakers, the buzzer offers advantages such as low power consumption, loud sound output, compact size, low cost, and high durability. In addition, due to its structural and material characteristics, the buzzer exhibits superior durability and stability even under extreme conditions such as high temperatures or high humidity. These features give the buzzer an irreplaceable advantage over speakers, which are more prone to damage and typically more expensive.

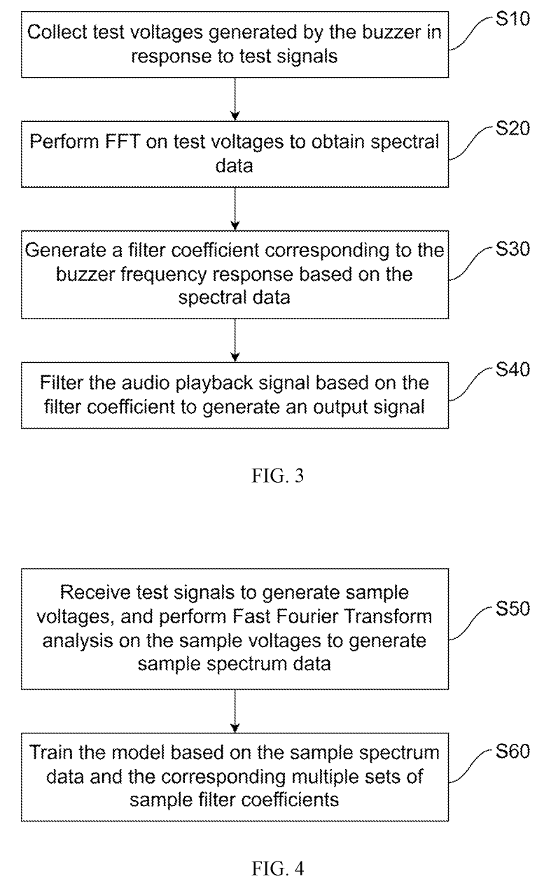

Referring to FIG. 3, a buzzer driving method with a signal compensation function according to an embodiment of the present invention is applied to the buzzer 2 and may be executed by the buzzer driving system 1. The buzzer driving method comprises the following steps.

S10: A plurality of test voltages generated by the buzzer 2 in response to a plurality of test signals are collected. Step S10 may be performed by the analog-to-digital conversion module 30, and the signal frequencies of the respective test signals are sequentially increased or decreased based on a predetermined frequency interval, that is, the signal frequencies of the test signals are sequentially spaced at a predetermined frequency interval.

Step S20: A fast Fourier transform (FFT) analysis is performed on the plurality of test voltages to generate spectrum data of the buzzer 2. Step S20 may be performed by the Fast Fourier Transform module 40.

Step S30: A filter coefficient corresponding to the frequency response of the buzzer 2 is generated based on the spectrum data by using neural network techniques. Step S30 may be performed by the neural network unit 21 of the control module 20.

S40: An audio playback signal is filtered based on the filter coefficient to generate an output signal for driving the buzzer 2. Step S40 may be performed by the filter module 10.

Referring to FIG. 4, another buzzer driving method with a signal compensation function according to another embodiment of the present invention further includes a model training process, which is used for training the neural network unit 21.

S50: A plurality of test signals are received to generate a plurality of sample voltages, and the plurality of sample voltages are subjected to fast Fourier transform (FFT) analysis to generate a plurality of sample spectral data. Preferably, the plurality of test signals are respectively received by a plurality of sample buzzers to generate the plurality of sample voltages. Each of the sample voltages from the respective sample buzzers is then subjected to FFT analysis to generate the corresponding plurality of sample spectrum data for the plurality of buzzers.

S60: Model training is performed based on the plurality of sample spectral data and the corresponding plurality of sample filter coefficients.

In summary, the buzzer driving system 1 with a signal compensation function according to the present invention first calculates the spectral data of the buzzer 2 through fast Fourier transform (FFT) analysis. A trained neural network unit 21 then generates a corresponding filter coefficient based on the spectral data. The filter module 10 is controlled to adjust its filter coefficient accordingly, such that the signal processing performed by the filter module 10 matches the frequency response of various buzzers 2. This allows signal compensation during filtering, thereby preventing signal distortion caused by the buzzer 2 and preserving more audio details. As a result, the buzzer 2 is able to retain the sound quality of the original audio signal, achieving audio performance comparable to conventional speakers while simultaneously maintaining the advantages of the buzzer 2, including high output volume, low component cost, and high durability.

The present invention has been disclosed herein by way of embodiments. However, it should be understood by those skilled in the art that the above embodiments are intended to illustrate, but not to limit, the scope of the patent rights claimed in the present invention. Any modifications or substitutions that are equivalent or have equivalent effects to the above embodiments should be interpreted as being included within the spirit or scope of the present invention. Therefore, the scope of protection of the present invention shall be defined by the following claims.

What is claimed is:

1. A buzzer driving system having a signal compensation function for use with a buzzer, the buzzer driving system comprising:
a control module having a neural network unit configured to generate a filter coefficient corresponding to a frequency response of the buzzer based on frequency spectrum data of the buzzer; and
a filter module configured to receive an audio playback signal and filter the audio playback signal based on the filter coefficient to generate an output signal.

2. The buzzer driving system according to claim 1, further comprising:
an analog-to-digital conversion module connected to the buzzer and configured to collect a plurality of test voltages generated by the buzzer in response to a plurality of test signals; and
a Fast Fourier Transform (FFT) module connected to the analog-to-digital conversion module and the control module, and configured to perform a Fast Fourier Transform analysis on the plurality of test voltages collected by the analog-to-digital conversion module to generate the frequency spectrum data.

3. The buzzer driving system according to claim 1, wherein the filter module comprises a finite impulse response (FIR) filter of N order, and the filter coefficient is an N-order filter coefficient.

4. The buzzer driving system according to claim 2, wherein each of the plurality of test signals has a different signal frequency, and the signal frequencies of the plurality of test signals increase or decrease sequentially based on a predetermined frequency interval.

5. The buzzer driving system according to claim 4, wherein each of the plurality of test signals has the same signal amplitude, and the plurality of test signals are superimposed on each other.

6. The buzzer driving system according to claim 1,
wherein the neural network unit is configured to perform model training based on a plurality of sample frequency spectrum data and a plurality of sample filter coefficients corresponding to the plurality of sample frequency spectrum data,
wherein each of the plurality of sample frequency spectrum data is generated by performing Fast Fourier Transform analysis on a plurality of sample voltages produced by a sample buzzer in response to a plurality of test signals.

7. A buzzer driving method with a signal compensation function for a buzzer, and the buzzer driving method comprising:
collecting a plurality of test voltages generated by the buzzer in response to a plurality of test signals;
performing Fast Fourier Transform analysis on the plurality of test voltages to generate frequency spectrum data of the buzzer;
generating a filter coefficient corresponding to a frequency response of the buzzer based on the frequency spectrum data using a neural network; and
filtering an audio playback signal based on the filter coefficient to generate an output signal for driving the buzzer.

8. The buzzer driving method according to claim 7, wherein the filter coefficient is an N-order filter coefficient of a finite impulse response (FIR) filter of N order.

9. The buzzer driving method according to claim 7, wherein each of the plurality of test signals has a different signal frequency, and the signal frequencies of the plurality of test signals increase or decrease sequentially based on a predetermined frequency interval.

10. The buzzer driving method according to claim 7, further comprising a model training process, wherein the model training process comprises:
receiving a plurality of test signals to generate a plurality of sample voltages;
performing Fast Fourier Transform analysis on the plurality of sample voltages to generate a plurality of sample frequency spectrum data; and
performing model training based on the plurality of sample frequency spectrum data and a plurality of sample filter coefficients corresponding to the plurality of sample frequency spectrum data.
